(19) United States
(12) Patent Application Publication
(10) Pub. No.: US 2022/0209191 A1
(43) Pub. Date: Jun. 30, 2022

(54) DISPLAY PANEL AND DISPLAY DEVICE USING THE SAME

(71) Applicant: LG Display Co., Ltd., Seoul (KR)

(72) Inventors: SeungRyong JOUNG, Seoul (KR); YoonDeok HAN, Yongin-si (KR); JeongEun WON, Incheon (KR); HeeSu BYEON, Paju-si (KR)

(73) Assignee: LG Display Co., Ltd., Seoul (KR)

(21) Appl. No.: 17/551,635

(22) Filed: Dec. 15, 2021

(30) Foreign Application Priority Data
Dec. 29, 2020 (KR) 10-2020-0186852

(51) Int. Cl. H01L 51/52

(52) U.S. Cl. CPC H01L 51/5265; H01L 2251/558; H01L 51/5275

(57) ABSTRACT

Disclosed are a display panel and a display device including the same. The display panel including: a substrate having first to third subpixels each including a reflective electrode, a first electrode vertically spaced apart from a lower surface of the reflective electrode by a gradually increasing distance, a white organic stack on the first electrode, a second electrode on the white organic stack, the second electrode having reflectivity and transmittance, and a thickness of from 20 nm to 50 nm, a capping layer on the second electrode, and a transparent protective layer on the capping layer.

### CROSS-REFERENCE TO RELATED APPLICATION

This application claims the benefit of and the priority to Korean Patent Application No. 10-2020-0186852, filed on Dec. 29, 2020, which is hereby incorporated by reference in its entirety as if fully set forth herein.

### BACKGROUND

### 1. Technical Field

The present disclosure relates to a display panel and a display device using the same. The display panel may secure a color gamut without a color filter layer in a structure in which the distance between a display surface and a viewer is fixed.

### 2. Description of the Related Art

Beyond monitors and televisions, display devices can be applied in a wearable form. For example, the display device may be mounted on a viewer, and may move together with the viewer. Such a display is mainly accommodated in an instrument mounted on the head of the viewer, and is configured to be held tightly to the viewer. Therefore, the area where the display device is disposed is limited to a predetermined physical space. For this reason, both integration and high luminance are required to realize a clearer display with higher resolution.

Such a wearable or mounted display device is different from large-area display devices in terms of the viewing angle and luminance characteristics and alignment density. Therefore, it is necessary to develop a different device structure to realize high integration and high luminance.

### SUMMARY

Accordingly, the present disclosure is directed to a display panel and a display device using the same, both of which substantially obviate one or more problems due to the limitations and disadvantages of the related art.

An aspect of the present disclosure is to provide a display panel that may secure a color gamut without a color filter layer in a structure in which the distance between a display surface and a viewer is fixed.

Another aspect of the present disclosure is to provide a display device using the display panel.

The display panel and the display device according to the present disclosure are capable of obviating an optical member limiting the emission efficiency of emission portions by changing the structure of an internal light-emitting element.

In addition to the objects of the present disclosure as mentioned above, additional advantages, objects, and features of the disclosure will be clearly understood by those skilled in the art from the following description of the disclosure. The objectives and other advantages of the disclosure may be realized and attained by the structure particularly pointed out in the written description and claims hereof as well as the appended drawings.

To achieve the above objects and other advantages in accordance with the purpose of the present disclosure, as embodied and broadly described herein, a display panel may comprise a substrate having first to third subpixels each including a reflective electrode, a first electrode vertically spaced apart from a lower surface of the reflective electrode by a gradually increasing distance, a white organic stack on the first electrode, a second electrode on the white organic stack, the second electrode having reflectivity and transmittance, and a thickness of from 20 nm to 50 nm, a capping layer on the second electrode, and a transparent protective layer on the capping layer.

In some example embodiments, the white organic stack may comprise a first stack comprising a first light-emitting layer to emit light of a blue wavelength, a first common layer under the first light-emitting layer, and a second common layer on the first light-emitting layer, and a charge generation layer contacting the second common layer. The display device may also comprise a second stack on the charge generation layer. The second stack may comprise a second light-emitting layer to emit light of a red wavelength, a third light-emitting layer to emit light of a green wavelength, the second light-emitting layer and third light-emitting layer being in contact with each other, a third common layer under the second light-emitting layer, and a fourth common layer on the third light-emitting layer.

In some example embodiments, the panel may be configured to emit light such that: light emitted from the first light-emitting layer at the first subpixel may be emitted in a single strong cavity mode through the second electrode, light emitted from the third light-emitting layer at the second subpixel may be emitted in a single strong cavity mode through the second electrode, and light emitted from the second light-emitting layer at the third subpixel may be emitted in a single strong cavity mode through the second electrode.

In some example embodiments, a difference in wavelengths of emission peaks of the first light-emitting layer and the second light-emitting layer may be from 135 nm to 174 nm.

In some example embodiments, the second electrode may have a thickness not less than 20 nm and not more than 35 nm, the first light-emitting layer may have an emission peak at a wavelength not less than 446 nm and not more than 464 nm, and the second light-emitting layer may have an emission peak at a wavelength not less than 612 nm and not more than 620 nm.

In some example embodiments, the second electrode may have a thickness more than 35 nm and not more than 50 nm, the first light-emitting layer may have an emission peak at a wavelength not less than 452 nm and not more than 467 nm, and the second light-emitting layer may have an emission peak at a wavelength not less than 602 nm and not more than 623 nm.

In some example embodiments, the first light-emitting layer may have an emission peak at a wavelength not less than 450 nm and not more than 470 nm, and the second light-emitting layer may have an emission peak at a wavelength not less than 600 nm and not more than 619 nm.

In some example embodiments, at the third subpixel, a full width at half maximum of light emitted to the second light-emitting layer through the second electrode may be not less than 10 nm and not more than 24 nm.

In some example embodiments, the first electrode may comprise a transparent oxide containing at least one of indium, zinc, and tin, and the second electrode may comprise at least one of magnesium, a magnesium alloy, silver, and a silver alloy.

In some example embodiments, the reflective electrode at the first subpixel and the first electrode may be in contact with each other. Also, the display panel may further comprise a transparent inorganic layer between the first electrode and the reflective electrode at the second subpixel and the third subpixel.

In some example embodiments, the transparent protective layer may comprise an encapsulation layer.

In some example embodiments, there may be no member limiting a color of emitted light on the transparent protective layer.

In some example embodiments, the display panel may further comprise a thin-film transistor at each of the first to third subpixels connected to the first electrode.

In some example embodiments, the substrate may comprise any one of a transparent glass substrate, a transparent plastic substrate, and a silicon substrate.

In another aspect of the present disclosure, a display device according to an example embodiment of the present disclosure may comprise a display panel, an accommodation structure to accommodate the display panel, and an air gap between the accommodation structure and the transparent protective layer. The display panel may comprise a substrate having first to third subpixels each including a reflective electrode, a first electrode vertically spaced apart from a lower surface of the reflective electrode by a gradually increasing distance, a white organic stack on the first electrode, a second electrode on the white organic stack, the second electrode having reflectivity and transmittance, and a thickness of 20 nm to 50 nm, a capping layer on the second electrode and a transparent protective layer on the capping layer.

In some example embodiments, the second electrode may have a thickness of from 20 nm to 50 nm.

In some example embodiments, the white organic stack may comprise a first stack comprising a first light-emitting layer to emit light of a blue wavelength, a first common layer under the first light-emitting layer, and a second common layer on the first light-emitting layer, and a charge generation layer contacting the second common layer. The display device may also comprise a second stack on the charge generation layer. The second stack may comprise a second light-emitting layer to emit light of a red wavelength, a third light-emitting layer to emit light of a green wavelength, the second light-emitting layer and third light-emitting layer contacting each other, a third common layer under the second light-emitting layer and a fourth common layer on the third light-emitting layer.

In some example embodiments, the first light-emitting layer may have an emission peak at a wavelength not less than 450 nm and not more than 470 nm, and the second light-emitting layer may have an emission peak at a wavelength not less than 600 nm and not more than 619 nm.

In some example embodiments, the display device is configured such that light passing through the second electrode of the display panel may be emitted through the air gap.

In some example embodiments, the display device is configured such that: light emitted from the first light-emitting layer at the first subpixel may be emitted in a single strong cavity mode through the second electrode, light emitted from the third light-emitting layer at the second subpixel may be emitted in a single strong cavity mode through the second electrode, and light emitted from the second light-emitting layer at the third subpixel may be emitted in a single strong cavity mode through the second electrode.

In some example embodiments, the substrate may be configured to be fixed at a predetermined distance from eyes of a viewer.

In some example embodiments, the display device is configured such that light passing through the second electrode may pass through the capping layer, the transparent protective layer, and the air gap, and has an identical light intensity ratio between red, green, and blue lights.

In some example embodiments, the display panel may comprise a first display panel and a second display panel separately disposed at regions in the accommodation structure, the regions correspond to both eyes of the viewer.

In some example embodiments, the display device may further comprise first and second lens units configured to converge an image to each eye of the viewer and be located between each of the first and second display panels and each eye of the viewer.

In some example embodiments, the accommodation structure is configured such that the first and second display panels may be each provided at sides of both eyes of the viewer, and the display device may further comprise first and second mirror reflective electrodes to reflect and transmit images emitted from the first and second display panels to the first and second lens units, respectively.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate example embodiment(s) of the disclosure and together with the description serve to explain the principle of the disclosure. In the drawings:

FIG. 1 is a cross-sectional view schematically illustrating a display device according to an example embodiment of the present disclosure;

FIG. 2 is a graph illustrating electroluminescence (EL) spectra of red, green, and blue light of the display panel of FIG. 1;

FIG. 3 shows, in part (a), an exploded view of a cross-section of a connection between an optical element and a thin-film transistor array of a display panel according to an example embodiment of the present disclosure, in part (b), a cross-sectional view illustrating a connection between an optical element and a thin-film transistor array of a display panel according to an example embodiment of the present disclosure, and in part (c), a cross-sectional view of the light-emitting units BEM, GEM, and REM, separated by a bank that surrounds the light-emitting units;

FIG. 4 is a cross-sectional view schematically illustrating a display device according to Experimental Example 1;

FIG. 5 is a graph illustrating the relationship between the thickness of the cathode of FIG. 4, efficiency, and an sRGB overlap;

FIGS. 6A and 6B are graphs illustrating EL spectra of red, green, and blue light passing through the capping layer of the white organic stack of Experimental Example 1 and Experimental Example 2, respectively;

FIGS. 7A and 7B are graphs illustrating the color space of light passing through the display panels of Experimental Examples 1 and 2, respectively;

FIG. 8 is a graph illustrating a contour map of Experimental Example 1 and red EL characteristics thereof;

FIG. 9 shows, in part (a), a graph illustrating a contour map of Experimental Example 2 and red EL characteristics thereof, and in part (b), a graph illustrating an EL spectrum of red light from red emission region REZ in Experimental Example 2;

FIG. 10 is a contour map for each color emitted by a display panel according to a first embodiment of the present disclosure;

FIG. 11 is a contour map for each color emitted by a display panel according to a second embodiment of the present disclosure;

FIG. 12 is a contour map for each color emitted by a display panel according to a third embodiment of the present disclosure;

FIG. 13 is a perspective view of a display device according to a first aspect of the present disclosure;

FIG. 14 is a top view of FIG. 13;

FIG. 15 is a perspective view of a display device according to a second aspect of the present disclosure; and

FIG. 16 is a diagram illustrating the relationship between the display device of FIG. 15 and a viewer's eye.

### DETAILED DESCRIPTION

Reference will now be made in detail to the embodiments of the present disclosure, examples of which are illustrated in the accompanying drawings.

Advantages and features of the present disclosure, and implementation methods thereof will be clarified through following example embodiments described with reference to the accompanying drawings. However, the present disclosure may be embodied in different forms and should not be construed as limited to the example embodiments set forth herein. Rather, these example embodiments of the present disclosure are provided so that this disclosure may be sufficiently thorough and complete to assist those skilled in the art to fully understand the scope of the disclosure. Further, the protected scope of the present disclosure is defined by claims and their equivalents.

The shapes, sizes, ratios, rates, angles, numbers, and the like, which are illustrated in the drawings to describe various example embodiments of the present disclosure, are merely given by way of example. Therefore, the present disclosure is not limited to the illustrations in the drawings.

In the following description of the example embodiments and the drawings, the same or similar elements are denoted by the same reference numerals even though they are depicted in different drawings. Wherever possible, the same reference numbers will be used throughout the drawings to refer to the same or like parts. The same or similar elements are designated by the same reference numerals throughout the specification unless otherwise specified.

In the following description, where the detailed description of the relevant known functions and configurations may unnecessarily obscure an important point of the present disclosure, a detailed description of such known functions or configurations may be omitted.

In the present specification, the terms “including,” “having,” and the like, will be interpreted as one or more other characteristics, numbers, steps, operations, elements or parts may be added, and do not exclude other characteristics, numbers, steps, operations, elements, parts or combinations thereof, or possibility of adding the same. An element described in the singular form is intended to include a plurality of elements, and vice versa, unless the context clearly indicates otherwise.

In interpreting an element in the various example embodiments of the present disclosure, the element is to be construed as including an error or tolerance range even where no explicit description of such an error or tolerance range is provided.

In the following description of the various embodiments, it should be understood that, where positional relations are described, for example, where an element is “on,” “above,” “under,” “beside,” and the like, another element, one or more other elements may be located between the two elements unless a more limiting term, such as “immediate(ly),” “direct(ly),” or “close(ly)” is used. For example, where an element or layer is disposed “on” another element or layer, a third layer or element may be interposed therebetween.

In the following description of the various embodiments, it should be understood that, when temporal relations are described, for example, the term expressing a sequence of events, such as “after,” “subsequent to,” “next to,” or “before,” a case which is not continuous may be included unless a more limiting term, such as “just,” “immediate(ly),” or “direct(ly),” is used.

In the following description of the various embodiments, it should be understood that, where the terms “first,” “second,” and the like, are used to describe various elements, these terms are used merely to distinguish the same or similar elements. These elements should not be limited by these terms as they are not used to define a particular order For example, a first element described hereinafter could be termed a second element, and vice versa, without departing from the scope of the disclosure.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of the various embodiments of the present disclosure may be partially or wholly coupled to or combined with each other, and may be variously inter-operated with each other and driven technically and interlocked with each other as those skilled in the art can sufficiently understand. Embodiments of the present disclosure may be carried out independently from each other, or may be carried out together in a co-dependent relationship.

In the following description of the various embodiments, a “doped” layer refers to a layer containing a host material and a dopant material that has properties different from the host material. Examples of host and dopant materials may include an N-type material and a P-type material or an organic material and an inorganic material. Apart from the differences in properties, the host and dopant materials may also differ in terms of their amounts in the doped layer. For example, the host material may be a major component while the dopant material may be a minor component. In some embodiments, an amount of dopant material is less than 30 wt %, based on a total weight of the doped layer.

In some embodiments, a layer may be made from organic materials only, which may include N-type and P-type materials. When the amount of the N-type material is less than 30 wt % or the content of the P-type material is less than 30 wt %, the layer may be a “doped” layer.

The term “undoped” describes layers that are not “doped.” For example, a layer may be an “undoped” layer when it is formed of a single material or a mix of materials having the same or similar properties. As a further example, a layer may be an “undoped” layer when at least one of materials forming a layer is P-type and none of the materials forming the layer is N-type. As another example, a layer may be an “undoped” layer when at least one of the materials forming a layer is organic and none of the materials forming the layer is inorganic.

In the following description of the various embodiments, an electroluminescence (EL) spectrum is obtained by multiplying (1) a photoluminescence (PL) spectrum, which shows the unique characteristics of a luminescent material, such as a dopant material or a host material included in an organic light emitting layer, with (2) an out-coupling emittance spectrum curve, which is determined according to the structure and optical characteristics of an organic light emitting device. These characteristics include, for example, thicknesses of organic layers such as an electron transport layer and the like.

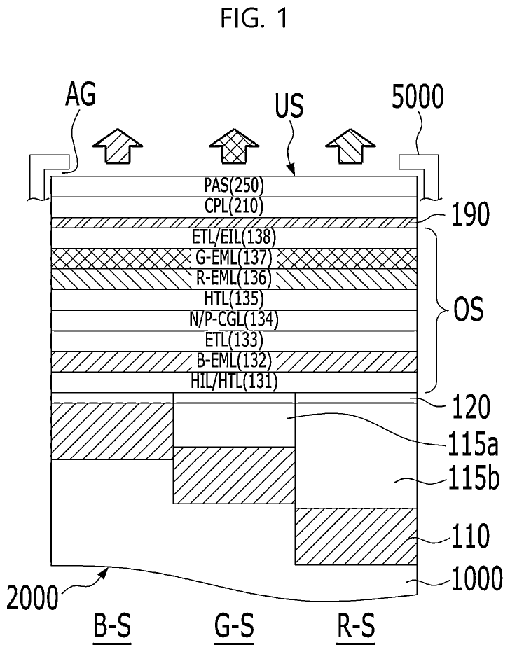

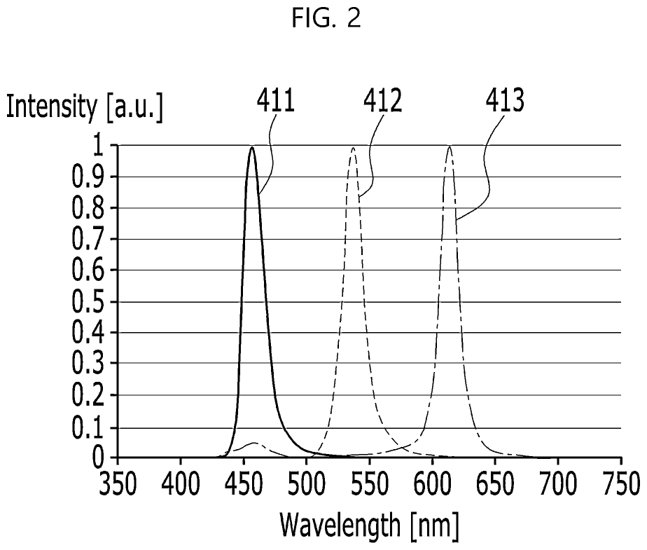

Hereinafter, the present disclosure will be described with reference to the drawings. FIG. 1 is a cross-sectional view schematically illustrating a display device according to an example embodiment of the present disclosure. FIG. 2 is a graph illustrating electroluminescence (EL) spectra of red, green, and blue light of the display panel of FIG. 1.

The display device of FIG. 1 is a display panel 2000 that may include an optical element configured to perform an optical function on a thin-film transistor array substrate 1000. The display panel may be accommodated by an accommodation structure 5000. First, among the terms described below, the optical element and the display panel will be described below.

The optical element described in the present disclosure may include an array form of a plurality of subpixels having organic light-emitting elements emitting different colors of light on a substrate in consideration of optical characteristics, and a plurality of members associated with light emission on the subpixels. In addition, the display panel may include a driving thin-film transistor for each subpixel to drive the optical element for each subpixel. In the display device of the present disclosure, the display panel may be provided to correspond to each of two eyes.

As shown in the example of FIG. 1, the display panel 2000 of an example embodiment of the present disclosure may include a substrate 1000 including first to third subpixels B-S, G-S, and R-S, a reflective electrode 110 provided in each of the first to third subpixels B-S, G-S, and R-S, a first electrode 120 disposed to be vertically spaced apart by a gradually increasing distance from the lower surface of the reflective electrode 110 in the first to third subpixels B-S, G-S, and R-S, and a white organic stack OS provided on the first electrode 120 and the second electrode 190 provided on the white organic stack OS in the first to third subpixels B-S, G-S, and R-S.

The second electrode 190 may have a thickness of 20 nm to 50 nm and is reflective and transmissive. In each subpixel B-S, G-S or R-S, light emitted from each light-emitting layer of the white organic stack OS may be repeatedly reflected between the reflective electrode 110 and the second electrode 190, so resonance may be generated, thereby ultimately improving the cavity characteristics of the light emitted to the second electrode 190. Accordingly, in the respective subpixels B-S, G-S, and R-S, electroluminescence spectra 411, 412, and 413 of blue, green, and red light may be generated within a narrow wavelength range, as shown in FIG. 2. In particular, blue light may be generated in a first curve 411, green light may be generated in a second curve 412, and red light may be generated in a third curve 413. Blue, green, and red light may be emitted from the subpixels B-S, G-S and R-S, respectively, without interference. That is, the second electrode 190 may be formed to a thickness of at least 20 nm, using a reflective metal to improve the resonance effect due to reflection and re-reflection of internal light. However, the second electrode 190 may be ultimately required to emit light, and light emission efficiency may be low when the second electrode is excessively thick. Thus, the thickness of the second electrode 190 may be adjusted to be 50 nm or less for the second electrode 190 to have at least a predetermined level of light emission efficiency.

Here, the second electrode 190 may be formed of a metal that has: (i) reflectivity to reflect light emitted from the white organic stack OS between the reflective electrode 110 and the white organic stack OS and (ii) transmittance to transmit light emitted from the second electrode 190. To this end, the second electrode 190 may be formed of magnesium, a magnesium alloy, silver, a silver alloy, or the like. The second electrode 190 may also be used in the form of an alloy of MgAg. Any metal or metal compound may also be used, as long as it has reflectivity and transmittance level at least as high as MgAg.

The first electrode 120 may be selected from materials that allow light to pass between the reflective electrode 110 and the white organic stack OS and that have low interfacial resistance with the organic material of the white organic stack OS. The first electrode 120 may be, for example, a transparent oxide containing at least one of indium (In), zinc (Zn), or tin (Sn) or a transparent nitride containing titanium (Ti), zinc (zinc), indium, or the like.

The reflective electrode 110 may be formed of a reflective metal containing any one of Ag, an Ag alloy, Al, an Al alloy, and APC (Ag:Pb:Cu), and may function as a mirror. The second electrode 190 may be a reflective transmissive electrode that functions as a half mirror, which amplifies and transmits only light with a specific wavelength determined by the resonance distance of the lower side of the second electrode 190, and repeatedly reflects the remaining amount of light between the reflective electrode 110 and the second electrode 190.

In the present disclosure, the second electrode 190 may be formed of AgMg or an alloy containing the same to improve the reflection characteristics between the reflective electrode 110 and the second electrode 190 and enhance the strong cavity characteristics depending on the resonance distance of each subpixel.

Here, in the first to third subpixels B-S, G-S, and R-S, the white organic stack OS having the same stack structure may be provided in the first electrode 120 and the second electrode 190. There may be a difference in the vertical spacing distance between the lower surface of the reflective electrode 110 and the first electrode 120, so improved emission between the reflective electrode 110 and the second electrode 190 may be achieved and the wavelength providing the fine resonance effect is changed.

Accordingly, when light is emitted from the light-emitting layers of the white organic stack OS in the first to third subpixels B-S, G-S, and R-S, the light transmitted upwards and downwards from the light-emitting layers may be repeatedly reflected from the surface of the reflective electrode 110 and the second electrode 190. Emission of light with a specific wavelength toward the second electrode 190 may be concentrated through the strong micro-cavity effect for the corresponding wavelength depending on the distance from the lower surface of the reflective electrode 110 to the second electrode 190. When the distance between the upper surface of the reflective electrode 110 and the second electrode 190 in each of the subpixels B-S, G-S, and R-S is defined as “d”, the equation 2 nd=mλ (where n is the average refractive index of the white organic stack, m is an integer, and λ is the wavelength of light having a microcavity in the corresponding subpixel and emitted from the second electrode 190) is satisfied. That is, the upper surface of the reflective electrode 110 may be vertically spaced from the first electrode 120 by a first distance (a), a second distance (b), and a third distance (c), to emit light of different colors from the first to third subpixels B-S, G-S, and R-S. The first distance (a) corresponds to the thickness of the reflective electrode 110, and thus the upper surface of the reflective electrode 110 in the first subpixel B-S contacts the first electrode 120. A reflection occurs from the upper surface of the reflective electrode 110 in each subpixel, and the presence of the first and second transparent inorganic layers 115a and 115b enables the formation of a resonance distance different from that of the first subpixel B-S and emission of resonant light between the electrode 110 and the second electrode 190.

Each of the second distance (b) and the third distance (c) may be greater than the first distance (a), the third distance (c) may be greater than the second distance (b). The distance adjustment may be performed by changing the thickness of the first and second transparent inorganic layers 115a and 115b between the reflective electrode 110 and the first electrode 120 in the second subpixel G-S and the third subpixel B-S.

Each of the first and second transparent inorganic layers 115a and 115b may have a refractive index difference of 0.3 or less with the first electrode 120. Each of the first and second transparent inorganic layers may enable transmission of most of light during the resonance of light between the reflective electrode 110 and the second electrode 190. The refractive index difference is used to determine the resonance wavelength of the corresponding subpixel in combination with the thickness of the white organic stack OS.

The first electrode 120 may be a transparent oxide electrode containing indium tin oxide (ITO) or indium zinc oxide (IZO), or a nitride electrode containing titanium (Ti), zinc (zinc), indium, or the like. The first electrode may be formed of a material that has excellent interfacial consistency with the first common layer 130 formed first in the white organic stack OS, transparency, and a work function that is the same as or similar to that of ITO, and directly improves the morphology of the interface with the organic layer through general surface treatment. In addition, the first electrode 120 may be formed of the same material as the second electrode 190 in some cases. However, both surfaces of the first electrode 120 may allow for transmission of light emitted from the electrode 110 unchanged in the upward direction or light emitted from the second electrode 190 unchanged in the downward direction, rather than specific reflection of the light, due to the small distance from the reflective electrode 110.

In the optical element of the present disclosure, the white organic stack OS may include a plurality of organic layers, and for example, different light-emitting stacks may be formed separately via a charge generation layer 134 (N/P CGL). The charge generation layer 134 may have a stack including an n-type charge generation layer (N CGL) and a p-type charge generation layer (P CGL), and may be a single layer including an n-type dopant and a p-type dopant in a host.

The first common layer 131 may include a hole injection layer HIL close to the first electrode 120 and a hole transport layer HTL on the hole injection layer HIL. In some cases, the first common layer 131 may further include an electron-blocking layer to reduce or prevent the transport of holes, or the escape of excitons or electrons from the first light-emitting layer 132 to the hole transport layer HTL.

The second common layer 133 may include an electron transport layer (ETL). The second common layer 133 may further include a hole-blocking layer that may be adjacent to the upper surface of the first light-emitting layer 132 and may be configured to reduce or prevent holes from escaping from the first light-emitting layer 132.

The third common layer 135 may include a hole transport layer (HTL). In some cases, the third common layer 135 may further include an electron-blocking layer. The fourth common layer 138 may have a stack including an electron transport layer (ETL) and an electron injection layer (EIL). The electron injection layer ETL may be configured to be in contact with the second electrode 190. Of the fourth common layer 138, the electron injection layer 138 may be formed of a metal and an inorganic material such as nitrogen, oxygen, or fluorine, and may be formed by feeding a different material using the same chamber in the previous step of formation of the second electrode 190.

One of the features of the white organic stack OS of the display panel 2000 according to an example embodiment of the present disclosure is that each organic layer may be formed to cover all subpixels, regardless of the type of subpixel (B-S, G-S, or R-S). The uppermost surface of the display panel 2000 according to an example embodiment of the present disclosure may be disposed close to the viewer's eyes, and may be spaced apart from the viewer's eyes by a predetermined distance. This is because the display panel 2000 may be accommodated in an accommodation structure 5000 so that the viewer wears the accommodation structure 5000 in the form of glasses or goggles on the eyes or the head.

Accordingly, the display panel 2000 may be applied to devices having a small size of about 3 inches or less, considering the eyeball movement in each eye and image sensing by the eyeball in relation to the fixed distance between the viewer's eye and the accommodation device on which the optical element is mounted.

For example, to display images corresponding to virtual reality and augmented reality in head-mounted display devices, high-resolution subpixels corresponding to 1,000 or more pixels (each pixel includes three or more subpixels) may be disposed within the aforementioned miniaturized area. In this case, the width of each subpixel may be less than 10 μm.

In such a high-resolution and highly integrated display panel, to dispose a different hole/electron transport layer or light-emitting layer in each subpixel, a different deposition mask may be required for each transport layer and each color of each light-emitting layer. However, an organic material deposition process using the deposition mask may be performed by disposing the deposition mask in a non-contact manner to be spaced apart from the substrate and then depositing a vaporized organic material. In this case, it may be difficult to implement a deposition mask having an opening having a fine width. Even when an opening having a fine width is used, the opening and the deposition site may not be completely aligned with each other due to interference at the edge of the opening, and the deposition site has a somewhat larger area than the opening or the deposition thickness varies at the edge of the opening. As such, when misalignment occurs between the deposition mask and the substrate, wrong location or deposition of the organic material to a different thickness in the same light-emitting portion may be a major cause of a reduction in yield.

Accordingly, the mountable display device requiring size reduction and high integration according to an example embodiment of the present disclosure may not divide the light-emitting layer for each sub-pixel. The mountable display device may include a plurality of stacks, each including a light-emitting layer, for each of all sub-pixels. As described above, in each sub-pixel, in the operation before the formation of the first electrode 120, the distance between the lower surface of the reflective electrode 110 and the second electrode 190 may be changed for each subpixel by the first and second transparent inorganic layers 115a and 115b. The vertical distance at which the resonance of light is generated for each subpixel may be adjusted. Thus, different selective microcavity wavelength characteristics may be provided for each subpixel.

In the display panel of the present disclosure, there may be no material selectively limiting the wavelength of light on the second electrode 190. That is, as shown in the example of FIG. 1, a capping layer (CPL) 210 and a transparent protective layer 250 that may protect the white organic stack OS and the second electrode 190 disposed thereunder and increase light emission efficiency may be further provided on the second electrode 190. In this case, a material for selectively limiting the wavelength of light, such as a color filter layer, a polarizing plate, or a color conversion layer, may not be disposed on the transparent protective layer 250. Therefore, the display panel according to an example embodiment of the present disclosure obviates the use of a material for limiting the intensity of emitted light on the second electrode, thereby improving the light emission efficiency. In this way, a reason for obviating the color filter layer may be that blue, green, and red light are emitted in a narrow wavelength range from the respective subpixels. In addition, when light of a specific color is emitted by changing the material of the light-emitting layer in the white organic stack OS, the overlap between the PL spectrum and out-coupling in which light of other color is emitted may be reduced to reduce or prevent leakage of light of other color. Here, each of the capping layer 210 and the transparent protective layer 250 may allow light to transmit at a transmittance of 80% or more, and may not be an optical member that emits light with wavelength selectivity of color.

Another optical member may not be directly attached to the upper surface US of the transparent protective layer 250. This may mean that, when described in relation to the accommodation structure 5000 configured to accommodate the display panel 2000, an optical member that transmits light with wavelength selectivity of color may not be provided between the display panel 2000 and the accommodation structure 5000.

For example, as illustrated, when the accommodation structure 5000 surrounds the periphery of the display panel 2000 and covers a part of the upper surface, a predetermined air gap (AG) between the display panel and the accommodation structure 5000 covering the periphery of the display panel 2000 may be provided. Also, the air gap may be formed between the upper surface US of the transparent protective layer 250 and the inner side surface of the upper structure of the accommodation structure 5000.

Although the capping layer 210 and the transparent passivation layer 250 are shown as single layers, embodiments of the present disclosure are not limited thereto. For example, the capping layer 210 may be a stack including an organic capping layer and an inorganic capping layer, or a stack including inorganic layers having different refractive indices. In addition, the transparent protective layer 250 may include at least one of a plurality of layers including an encapsulation layer, a protective layer, a barrier layer, and a UV blocking layer.

For example, the white organic stack OS may include a first stack including a first light-emitting layer (B-EML) 132 configured to emit light with a blue wavelength, and a first common layer 131 may be provided under or on the first light-emitting layer 132, and a second common layer 133, a charge generation layer 134 contacting the second common layer 133, and a second stack disposed on the charge generation layer 134 and including a second light-emitting layer (R-EML) 136 configured to emit light of a red wavelength and a third light-emitting layer (G-EML) 137 configured to emit light of a green wavelength and to contact the second light-emitting layer (R-EML) 136, a third common layer 135 disposed under the second light-emitting layer 136, and a fourth common layer 138 disposed on the third light-emitting layer 137.

In the first subpixel (B-S), light emitted from the first light-emitting layer (B-EML) 132 may be emitted in a single strong cavity mode through the second electrode 190. In the second subpixel (G-S), light emitted from the third light-emitting layer (G-EML) 137 may be emitted in a single strong cavity mode through the second electrode 190. In the third subpixel (R-S), light emitted from the second light-emitting layer (R-EML) 136 may be emitted in a single strong cavity mode through the second electrode 190.

The thickness of the white organic stack OS may be set to emit blue light from the first light-emitting layer 132 under the improved resonance conditions. Therefore, the first subpixel B-S may emit blue light in an EL spectrum having a narrow full width at half maximum (FWHM).

In addition, the distance between the reflective electrode 110 and the second electrode 190 may be increased by the first transparent inorganic layer 115a in the second subpixel G-S, compared to the first subpixel B-S, so green light may be favorably resonated and emitted. Accordingly, in the second subpixel G-S, blue light may be emitted in an EL spectrum having a narrow full width at half maximum (FWHM).

In addition, the distance between the reflective electrode 110 and the second electrode 190 may be increased by the second transparent inorganic layer 115b, which may be thicker than the first transparent inorganic layer 115a, in the third subpixel R-S, compared to the first and second subpixels B-S and G-S. Therefore, red light is favorably resonated and emitted. Accordingly, in the third subpixel R-S, blue light may be emitted in an EL spectrum having a narrow full width at half maximum (FWHM).

The first light-emitting layer 132 may be a blue light-emitting layer, which includes a blue dopant and a blue host. The second light-emitting layer 136 may be a red light-emitting layer, which includes a red dopant and a red host. The third light-emitting layer 137 may be a green light-emitting layer, which includes a green dopant and a green host.

The dopant in each light-emitting layer adjusts the emission wavelength of the light-emitting layer. The host may facilitate the excitation of the dopant in the light-emitting layer, and may reduce or prevent holes and electrons from escaping from the light-emitting layer. The first to third light-emitting layers 132, 136, and 137 may have different dopants and the same or different hosts. In addition, the number of hosts in each light-emitting layer may be one or more.

The material for the red host may be selected from the group consisting of a substituted or unsubstituted aryl group having 6 to 24 carbon atoms, a substituted or unsubstituted heteroaryl group, a substituted or unsubstituted condensed aryl group having 10 to 30 carbon atoms, a substituted or unsubstituted heteroaryl group having 2 to 24 carbon atoms, a substituted or unsubstituted alkyl group having 1 to 24 carbon atoms, a substituted or unsubstituted heteroalkyl group having 1 to 24 carbon atoms, a substituted or unsubstituted cycloalkyl group having 3 to 24 carbon atoms, a substituted or unsubstituted alkoxy group having 1 to 24 carbon atoms, a substituted or unsubstituted aryloxy group having 6 to 24 carbon atoms, a substituted or unsubstituted alkylsilyl group having 1 to 24 carbon atoms, a substituted or unsubstituted aryl silyl group having 6 to 24 carbon atoms, a cyano group, a halogen group, deuterium and hydrogen. Each core group of the red host may form a condensed ring with an adjacent substituent.

In addition, the material for the red host may have an aryl or heteroaryl group as a core. The core may be one or more of: phenyl, naphthalene, fluorene, carbazole, phenazine, phenanthroline, phenanthridine, acridine, cinnoline, quinazoline, quinoxaline, naphthyridine, phthalazine, quinolizine, indole, indazole, pyridazine, pyrazine, pyrimidine, pyridine, pyrazole, imidazole, and pyrrole. Examples of the red host material of the second light-emitting layer 136 (R-EML) include 4,4′-bis(N-carbazolyl)-1,1′-biphenyl (CBP), 4,4′-bis(9-carbazolyl)-2,2′-dimethylbiphenyl (CDBP), 1,3-bis(N-carbazolyl)benzene (mCP), bathocuproine (BCP), bis(8-hydroxy-2-methylquinoline)-(4-phenylphenoxy)aluminum (BAlq), 3-(Biphenyl-4-yl)-5-(4-tert-butylphenyl)-4-phenyl-4H-1,2,4-triazole (TAZ), and the like, and the red host material may include one or more of the above materials.

In addition, the second light-emitting layer 136 (R-EML) may include a dopant to emit red light. The dopant may be a phosphorescent dopant which includes, but is not limited to, Ir(piq)₃(Tris(1-phenylisoquinoline)iridium(III), Ir(piq)₂(acac)(Bis(1-phenylisoquinoline)(acetylacetonate)iridium(III), Ir(bip)₂(acac)(Bis)2-benzolbithiophen-2-yl-pyridime)(acetylacetonate)iridium(III)), and Ir(BT)₂(acac)(Bis(2-pheylbenzothazolato)(accetylacetonate)iridium(III).

In addition, examples of the fluorescent dopant that may be included in the second light-emitting layer 136 (R-EML) include Rubrene (5,6,11,12-tetraphenylnaphthacene), DCJTB (4-(dicyanlmethylene)-2-tert-butyl-6-(1,1,7,7,-tetramethyljuloidin-4-yl-viyl)-4H) and the like.

In addition, examples of the green host included in the third light-emitting layer 137 (G-EML) include C-545T (10-(2-benzothia-zylyl)-1,1,7,7-tetramethyl-2,3,6,7-tetrahydro-1H,5H,11H-[1]benzo-pyrano[6,7,8-ij]quinolizin-11-ne), tris(8-hydroxyquinolinato)aluminium (Alq₃) and derivatives thereof, quinacridone derivatives, and carbazole derivatives. When Alq₃ is used as the host, green light may be emitted by itself. However, a green dopant may be included to improve the emission efficiency of green light, and both phosphorescent and fluorescent dopants may be used as the green dopant.

Here, the material for the first light-emitting layer 132 (B-EML) may include at least one blue host and at least one blue dopant. For example, a fluorescent blue dopant may be doped into at least one fluorescent host material selected from the group consisting of an anthracene derivative, a pyrene derivative, a boron-based compound, and a perylene derivative. If a stable phosphorescent blue material is developed, it may be used as an alternative.

However, in the display panel according to an example embodiment of the present disclosure, the first light-emitting layer 132 may have an emission peak at a wavelength not less than 450 nm and not more than 470 nm, and the second light-emitting layer 136 may have an emission peak at a wavelength not less than 600 nm and not more than 619 nm. In this case, the blue dopant of the first light-emitting layer 132 may be a material having a PL (photoluminescence) peak with a relatively long wavelength within a blue wavelength range, and the red dopant of the second light-emitting layer 136 may be a material having a relatively short wavelength within a red wavelength range. Based thereon, when the third subpixel R-S is selectively turned on, there may be almost no overlap between the PL spectrum of light emitted from the second light-emitting layer 136 in the white organic stack OS and the out-coupling spectrum by light emitted from the remaining light-emitting layers 132 and 137. Therefore, red light may be emitted without leakage in the third subpixel R-S and the PL spectrum may be almost similar to the PL spectrum of the second light-emitting layer 136. For example, the substituents of the dopant materials described above may be changed to control the PL peaks of the red dopant and the blue dopant.

Hereinafter, an example thin-film transistor array substrate 1000 will be described in detail.

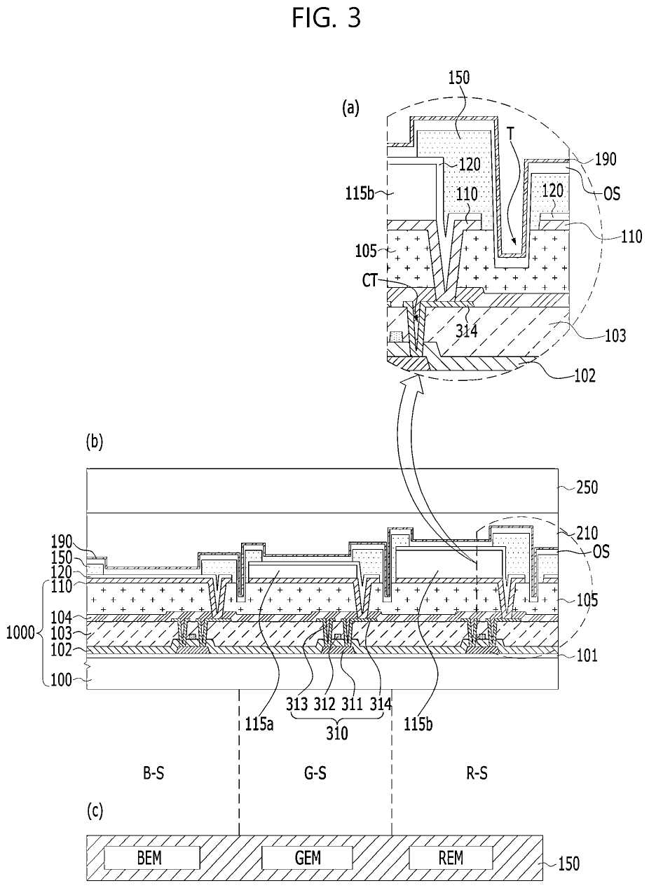

FIG. 3 shows, in part (a), an exploded view of a cross-section of a connection between an optical element and a thin-film transistor array of a display panel according to an example embodiment of the present disclosure, in part (b), a cross-sectional view illustrating a connection between an optical element and a thin-film transistor array of a display panel according to an example embodiment of the present disclosure, and in part (c), a cross-sectional view of the light-emitting units BEM, GEM, and REM, separated by a bank that surrounds the light-emitting units.

As shown in the examples of FIG. 3, in the display panel according to an example embodiment of the present disclosure, the thin-film transistor array substrate 1000 on which a first reflective electrode 110 of each subpixel B-S, G-S, or R-S is formed may have the following configuration. That is, the example thin-film transistor array substrate 1000 may include a buffer layer 101 on a substrate 100 including first to third subpixels B-S, G-S, and R-S, and a driving thin-film transistor 310 in each of the subpixels B-S, G-S, and R-S on the buffer layer 101 and may include the optical element disposed to be connected to each of the driving thin-film transistors 310 as described with reference to the example of FIG. 1 above.

In the display panel according to an example embodiment of the present disclosure, the substrate 100 may be, for example, any one of a transparent glass substrate, a transparent plastic substrate, and a silicon wafer substrate. In addition, the substrate 100 may be mounted on the head of a viewer and thus may be formed of a flexible material having flexibility according to the curvature of the accommodation structure of the head-mounted display device.

In addition, when the substrate 100 is mounted on the accommodation structure and positioned outside both eyes, or there may be no need to accommodate an external image even when it corresponds to the line of sight, for example, in virtual reality, the substrate 100 may be formed of a nontransparent material such as silicon wafer. When the substrate 100 is in the line of sight and corresponds to both eyes of the viewer, and when it may be desirable or necessary to accommodate an external image together, for example, in augmented reality, the substrate 100 may be transparent.

Here, each driving thin-film transistor 310 may be electrically connected to the first electrode 120. In the illustrated example, the reflective electrode 110 may be formed as a reflective electrode, thus enabling the first electrode 120 and the reflective electrode 110 to be electrically connected. In some cases, the reflective electrode 110 may be only optically reflective and thus may not have electrical conductivity, or may be formed of a reflective material rather than an electrode, and thus may not be directly electrically connected to the first electrode 120. In the second subpixel G-S and the third subpixel R-S, a first transparent inorganic layer 115a and a second transparent inorganic layer 115b may be further provided between the reflective electrode 110 and the first electrode 120 to adjust the distance between the lower surface of the reflective electrode 110 and the second electrode 190.

The driving thin-film transistor 310 may include a semiconductor layer 311 provided in a predetermined region of the buffer layer, and a gate electrode 312 partially overlapping with the semiconductor layer 311 via a gate insulating film 102 interposed therebetween on the semiconductor layer 311, and a source electrode 313 and a drain electrode 314 connected to both sides of the semiconductor layer 311. In the illustrated example, a top gate structure in which the gate electrode 312 is disposed on the semiconductor layer 311 may be provided, but embodiments of the present disclosure are not limited thereto. A bottom gate structure, in which the gate electrode is disposed under the semiconductor layer, may also be formed.

In addition, the semiconductor layer 311 may be applied in the form of a polysilicon, amorphous silicon, or oxide semiconductor layer, or a combination thereof. In some cases, the semiconductor layer 311 may be formed to be crystalline only in the portion excluding a channel.

In addition, an interlayer insulating layer 103 may be further provided on the gate insulating layer 102, such that it may cover the gate electrode 103 and corresponds to the lower portions of the source electrode 313 and the drain electrode 314. An inorganic passivation layer 104 and an organic passivation layer 105 may be sequentially formed on the interlayer insulating layer 103 to cover the source electrode 313 and the drain electrode 314. The source electrode 313 and the drain electrode 314 may be connected to the semiconductor layer 311 disposed thereunder through a contact hole CT provided in the interlayer insulating layer 103 and the gate insulating layer 102.

The organic passivation layer 105 may be formed to have a thickness of 1 μm or more to offset the thickness difference in the lower structure and may have a flat surface. In addition, the reflective electrode 110, which is formed of aluminum (Al), an aluminum alloy, silver, a silver alloy, APC, or the like. Thus, the reflective electrode 110 has conductivity, may be connected to the drain electrode 314 through the contact hole in the organic passivation layer 105 and the inorganic passivation layer 104.

In the display panel according to an example embodiment of the present disclosure, the light-emitting units BEM, GEM, and REM of the respective subpixels may be separated by a bank 150 surrounding the light-emitting units. A trench T between adjacent subpixels may be excavated to a depth corresponding to a partial thickness of the organic passivation layer 105 between the banks 150 to separate the subpixels from one another. The trench T may be provided to realize structural isolation between subpixels of the organic layers through reduced deposition of organic materials in the vertical portion of the trench when multiple organic layers constituting the white organic stack OS are formed regardless of subpixels in a miniaturized and highly integrated device like the display panel of the present disclosure.

In addition, the bank 150 may be formed as an inorganic film such as an oxide film (SiOx) or a nitride film (SiNx). This may be because when forming the bank 150 with an organic material, it may be difficult to control the fine line width. Whereas, when forming the bank 150 with an inorganic film, it may be possible to adjust a line width to several micrometers (μm), to increase resolution, and even to adjust the line width on the nanometer scale.

The configurations of the white organic stack OS, the second electrode 190, the capping layer 210, and the transparent protective layer 250 provided in the respective subpixels B-S, G-S, and R-S, and the materials for the first electrode 120 and the reflection electrode 110 may be the same as those described with reference to the example of FIG. 1. The light-emitting units BEM, GEM, and REM of the respective subpixels may be defined in inner regions of the bank 150. To describe the effects of the display panel of the present disclosure described above, a comparison between Experimental Examples 1 and 2 is described below.

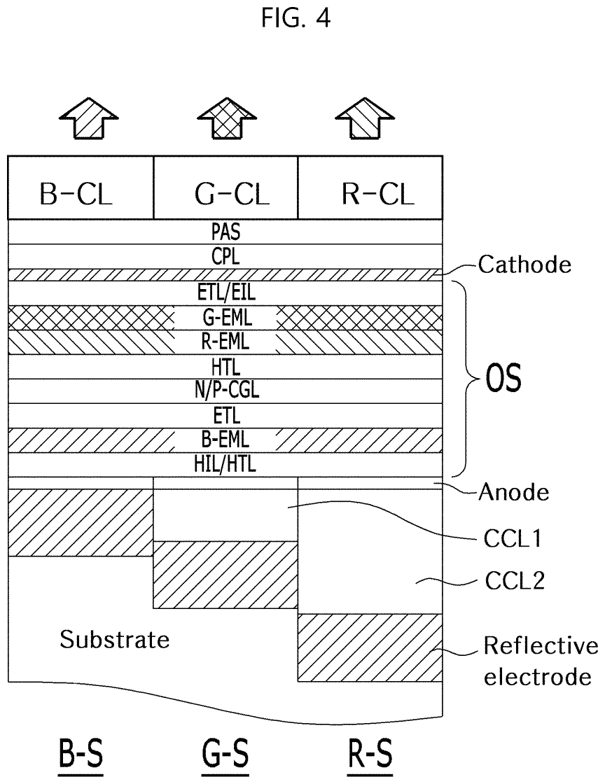

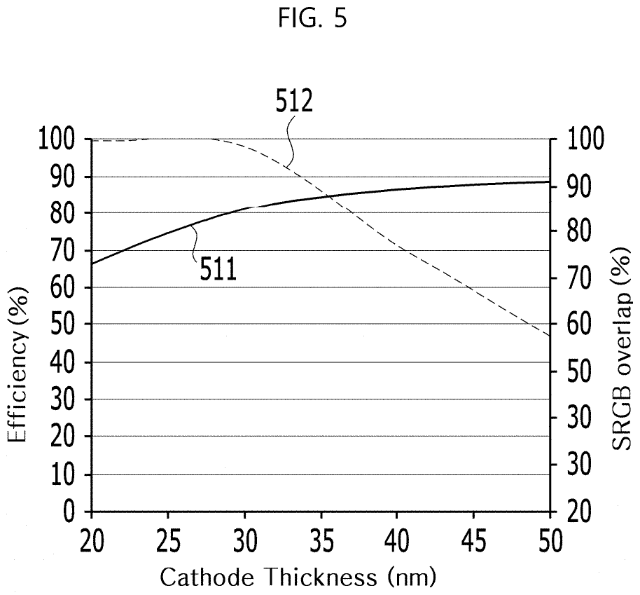

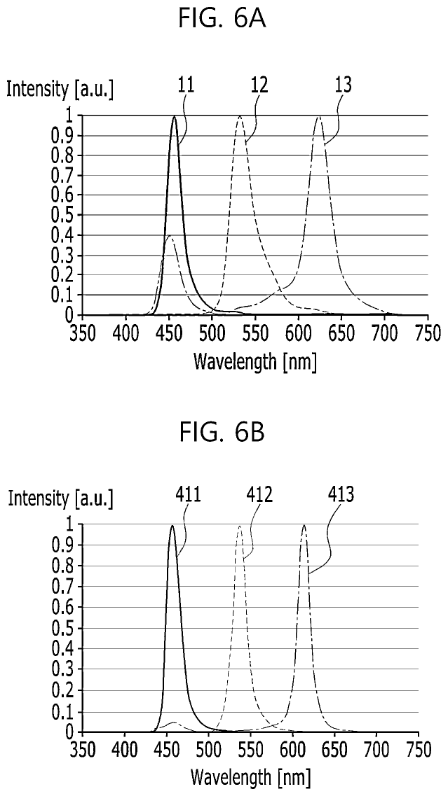

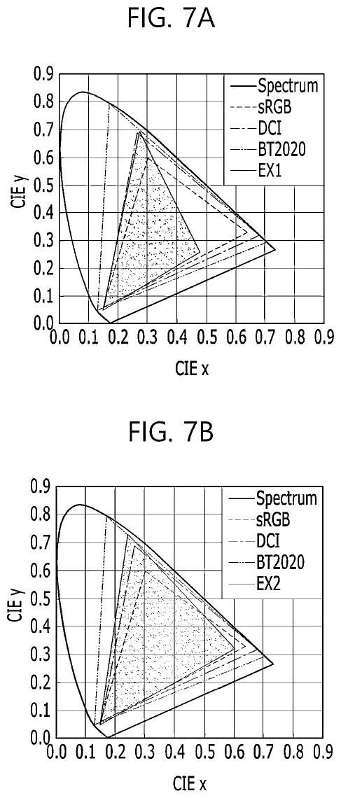

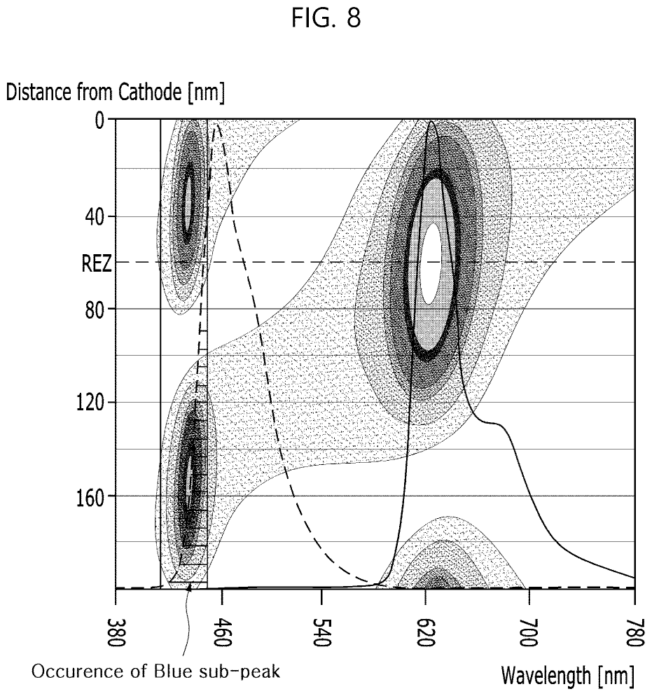

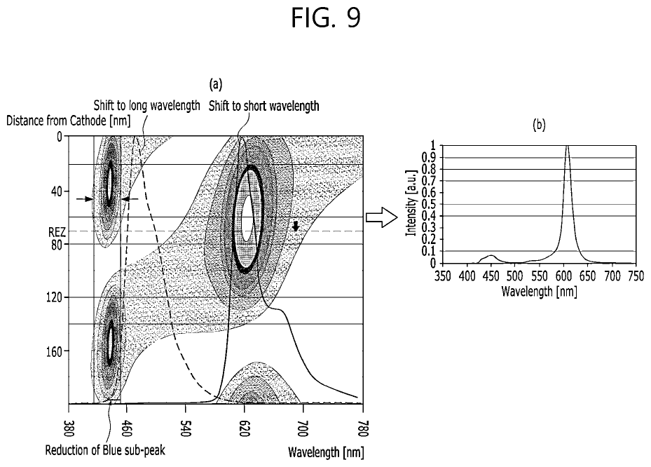

FIG. 4 is a cross-sectional view schematically illustrating a display device according to Experimental Example 1 (Ex1). FIG. 5 is a graph illustrating the relationship between the thickness of the cathode of FIG. 4, efficiency, and an sRGB overlap. FIGS. 6A and 6B are graphs illustrating EL spectra of red, green, and blue light passing through the capping layer of the white organic stack of Experimental Example 1 and Experimental Example 2. FIGS. 7A and 7B are graphs illustrating the color space of light passing through the display panels of Experimental Examples 1 and 2. FIG. 8 is a graph illustrating a contour map of Experimental Example 1 and red EL characteristics thereof. FIG. 9 shows, in part (a), a graph illustrating a contour map of Experimental Example 2 and red EL characteristics thereof, and in part (b), a graph illustrating an EL spectrum of red light from red emission region REZ in Experimental Example 2.

Experimental Example 2 (Ex2) corresponds to the structure described in the example of FIG. 1, and does not include an optical member that selectively limits light in a wavelength-dependent manner on the transparent protective layer. In Experimental Examples 1 and 2 (Ex1, Ex2), the PL peak characteristics of the blue light-emitting layer (B-EML) and the red light-emitting layer (R-EML) were different. In Experimental Example 1 (Ex1), the blue light-emitting layer (B-EML) had a PL peak of 456 nm, and the red light-emitting layer (R-EML) had a PL peak of 624 nm. The PL peak of the blue light-emitting layer shifted to a longer wavelength and the PL peak of the red light-emitting layer shifted to a shorter wavelength in Experimental Example 2 (Ex2), compared to Experimental Example 1 (Ex1). In Experimental Example 2 (Ex2), the PL peak of the blue light-emitting layer was 463 nm and the PL peak of the red light-emitting layer was 616 nm.

In Experimental Example 1 (Ex1), as shown in the example of FIG. 4, the blue color filter layer (B-CL), the green color filter layer (G-CL), and the red color filter layer (R-CL) were formed in the first to third subpixels, R-S, G-S, and B-S, respectively, on the transparent protective layer. Although Experimental Example 1 (Ex1) had the same configuration as the example illustrated in FIG. 1, Experimental Example 1 had additional color filter layers, as described above, making the upper structure of Ex1 different from that of FIG. 1. In Experimental Example 1, the first light-emitting layer B-EML had a characteristic emission peak at a short wavelength within a blue wavelength range and the second light-emitting layer R-EML had a characteristic emission peak at a long wavelength within a red wavelength range.

For example, Experimental Example 1 (Ex1) of the example of FIG. 4 was tested under the conditions that the emission peak of the first light-emitting layer (B-EML) was 456 nm and the emission peak of the second light-emitting layer (R-EML) was 624 nm.

Experimental Example 2 (Ex2) had the structure of the example of FIG. 1 described above and did not have any color filter layer in the upper structure. This structure was tested under the conditions that the emission peak of the first light-emitting layer 132 was 463 nm and the emission peak of the second light-emitting layer 136 was 616 nm.

In Experimental Example 1, the emission efficiency of the light passing through the second electrode at different thicknesses of the second electrode and the sRGB color space overlap (%) were evaluated according to Tables 1 and 5. As the thickness of the second electrode increased, the color gamut effect increased and the sRGB color space overlap (%) increased, as shown by the first curve 511. But the emission efficiency decreased relatively, as shown by the second curve 512. Here, the sRGB color space overlap (%) is a characteristic of the emitted light before passing through the blue color filter layer (B-CL), the green color filter layer (G-CL), and the red color filter layer (R-CL). In Experimental Example 1, the final emission efficiency of light after passing through each color filter layer was lower than the value shown in Table 1.

TABLE 1

| Thickness of | | |
|---|---|---|
| second electrode | sRGB color | |
| [nm] | space overlap (%) | Efficiency (%) |
| 20 | 74 | 100 |
| 30 | 85 | 98 |
| 40 | 89 | 71 |

For example, the luminescence characteristics of Experimental Example 1 (Ex1) will be described with reference to FIGS. 6A, 7A, and 8. Considering the EL spectrum in the state in which the first subpixel B-S, the second subpixel G-S, and the third subpixel R-S were selectively turned on in Experimental Example 1, each of blue light of the first curve 11, green light of the second curve 12, and red light of the third curve 13 appeared as shown in FIG. 6A. However, as in the third curve 13, blue light leaked when red light was emitted. This means that when the red subpixel was turned on, some blue light escaped, thus making it difficult to reproduce pure red color in Experimental Example 1 (Ex1).

That is, as shown in FIG. 7A, in Experimental Example 1 (Ex1), no overlap occurred, for example, in the red region, compared with the sRGB color space standard, the DCI color space standard, and the BT2020 color space standard. In Experimental Example 1 (Ex1) of FIG. 7A, the thickness of the second electrode was 20 nm.

Among the color gamut values in the table above, sRGB is a standard color space, created by HP and Microsoft in 1996, based on the lowest values among the examples presented as Standard RGB. DCI stands for “Digital Cinema Initiatives” that may be expressed by a digital cinema, and BT2020 is a standard of 4K/UHD recommended by ITU, an international broadcasting standardization organization, and is also called “Rec.2020”. For reference, the standards are stricter and increase in color expression area in the ascending order of sRGB, DCI, and BT2020.

A contour map when the red subpixel was turned on in Experimental Example 1 (Ex1) is described with reference to FIG. 8. Upon emission of red light, when a voltage difference was applied to the first electrode (anode) and the second electrode (cathode) of the third subpixel R-S to turn on the white organic stack OS, the first to third light-emitting layers (B-EML, R-EML, G-EML) emitted light. A red emission region REZ in the white organic stack OS was observed at a PL peak wavelength of 624 nm. However, red light having a PL peak wavelength of about 624 nm in the red emission region REZ was mainly emitted from the second light-emitting layer R-EML, and at the same time, blue light was concomitantly emitted due to the outcoupling of the white organic stack by light emitted by the first light-emitting layer B-EML at a wavelength of approximately 450 nm±15 nm. The reason for the presence of the sub-peak of blue light is that the outcoupling spectrum of the light generated in the first light-emitting layer B-EML had a large area overlapping the PL peak of the red dopant in the second light-emitting layer. This is considered to cause a reduction in color gamut, as shown in FIG. 7A.

TABLE 2

| | | | | Color efficiency (%) (compared to | | |
|---|---|---|---|---|---|---|
| | Blue PL | Red PL | sRGB | Experimental Example 1) | | |
| Item | peak [nm] | peak [nm] | overlap (%) | Red | Green | Blue |
| Ex1 | 456 | 624 | 89 | 100 | 100 | 100 |
| Ex2 | 463 | 616 | 97 | 105 | 100 | 86 |

Table 2 shows the sRGB color space overlap, and the color efficiency when the thickness of the second electrode (cathode) in each of Experimental Examples 1 and 2 (Ex1 and Ex2) was 40 nm. Here, “color efficiency” refers to the color efficiency of each of red, green, and blue of Experimental Example 2 (Ex2), expressed as a percentage of the color efficiency of Experimental Example 1 (Ex1). With reference to Table 2, the red color efficiency of Experimental Example 2 (Ex2) was improved compared to Experimental Example 1 (Ex1), and the blue color efficiency of Experimental Example 2 (Ex2) was reduced compared to Experimental Example 1 (Ex1).

When the blue color efficiency of Experimental Example 2 (Ex2) was lower than that of Experimental Example 1 (Ex1), this means that white was realized by increasing red efficiency and lowering blue efficiency based on a white color efficiency created by driving all of the first to third subpixels.

As described with reference to FIGS. 1 and 2, in Experimental Example 2 (Ex2), as shown in FIG. 6B, all of the EL spectra 411, 412, and 413 of the blue, green, and red light-emitting layers were generated at a narrow wavelength; for example, for each of blue, green, and red, the EL spectrum of Experimental Example 2 (Ex2) had a narrower full width at half maximum than that of the EL spectrum of Experimental Example 1 (Ex1). In addition, the full width at half maximum of the EL spectrum 413 of the red light-emitting layer was about ½ as wide as that of the third curve 13 of Experimental Example Ex1. In this case, in the third subpixel (R-S: red pixel), the full width at half maximum of light emitted from the second light-emitting layer (R-EML: red light-emitting layer) through the second electrode (cathode) 190 was not less than 10 nm and not more than 24 nm.

As can be seen from Experimental Example 2 (Ex2) of FIG. 7B, Experimental Example (Ex2) almost completely overlapped the sRGB color space standards, forming color spaces, and overlapped the sRGB color spaces in both the blue and red regions. This means that the coverage with sRGB was improved in Experimental Example 2 (Ex2) compared to Experimental Example 1 (Ex1) by changing the PL characteristics of the dopants of the first and second light-emitting layers (B-EML, R-EML) in the white organic stack OS.

Light emission during selective driving of the red light-emitting layer of an example embodiment of the present disclosure will be described with reference to FIG. 9.

As shown in FIG. 9, upon emission of red light, when a voltage difference was applied to the first electrode (anode) and the second electrode (cathode) of the third subpixel R-S to turn on the white organic stack OS, the first to third light-emitting layers (B-EML, R-EML, G-EML) emitted light. In Experimental Example 2 (Ex2), the emission peak of the red light-emitting layer in the white organic stack OS shifted to a shorter wavelength, and a PL peak occurred at a wavelength of 616 nm. In this case, as the red PL peak shifted to a shorter wavelength, the red emission region REZ in the white organic stack OS may also be adjusted downwards compared to Experimental Example 1 (Ex1).

Here, in Experimental Example 2 (Ex2), the emission peak of the red dopant in the red light-emitting layer shifted to a shorter wavelength. The emission peak of the blue dopant in the blue light-emitting layer shifted to a longer wavelength. Therefore, concomitant emission of blue light was reduced by reducing the overlap between the PL spectrum of the red light and the outcoupling region caused by light emitted by the first light-emitting layer (B-EML) disposed in a lower portion when the red subpixel emitted light. This means that the sub-peak of blue light was reduced when driving the red subpixel by reducing the area in which the outcoupling spectrum of light generated from the first light-emitting layer B-EML overlapped the PL peak of the red dopant in the second light-emitting layer.

When blue or green light is selectively emitted from the display panel of an example embodiment according to the present disclosure, the problem of light leakage that occurs when red light is emitted is overcome. For each light-emitting layer to emit light, holes combine with electrons in the light-emitting layer to form excitons, and the energy thereof falls to the ground state, whereby light is emitted. The excitation energy required for green light emission and blue light emission is smaller than that for red light emission. Accordingly, when the first and second subpixels B-S and G-S selectively emit light, they are used to transport holes and electrons from the red light-emitting layer to the third common layer (HTL in the second stack) adjacent thereto and the green light-emitting layer G-EML, and almost no red light is emitted, so selective light emission of each subpixel may not be inhibited.

The color efficiency and efficiency of Experimental Example 1 (Ex1) and Experimental Example 2 (Ex2) were considered in the state in which the color filter was excluded from each structure, as described above. In Experimental Example 1 (Ex1), blue light leaked when the red subpixel emitted light, and therefore, as shown in the example of FIG. 4, the use of a color filter was required. In this case, Experimental Example 1 may have lower efficiency than that shown in Table 1 above. Like Experimental Example 2, the display panel of the present disclosure has advantages of increasing pure color efficiency for each color of emitted light without using a color filter, and thus improving the efficiency of the emitted light by obviating the optical member that limits the amount of light emitted for each wavelength from the upper portion of the display panel including the transparent protective layer.

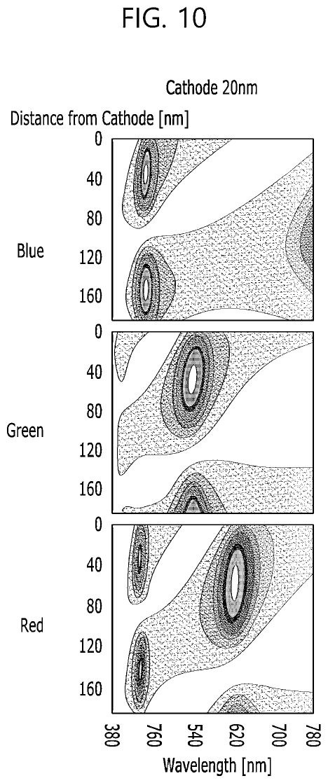

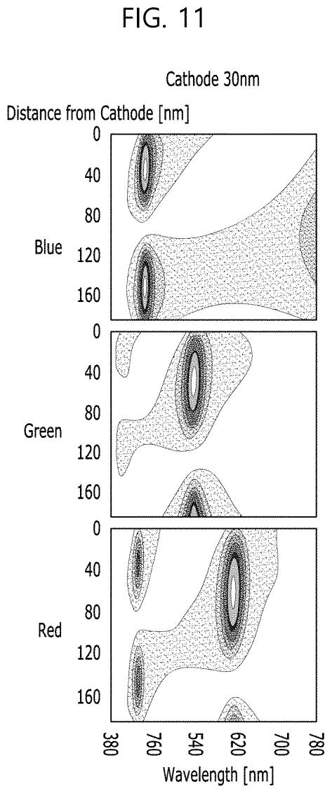

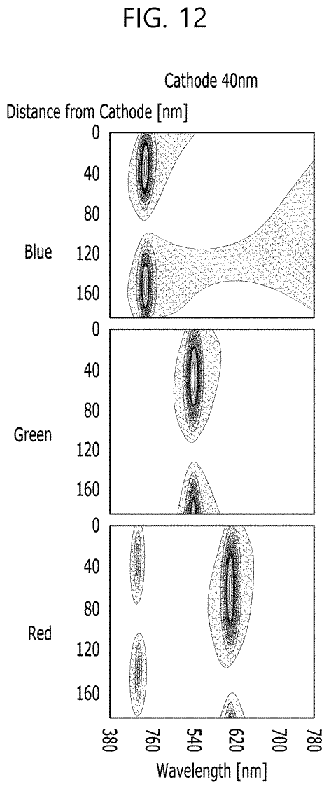

Hereinafter, the effects of varying the thickness of the second electrode in the display panel according to various embodiments of the present disclosure will be described. FIG. 10 is a contour map for each color emitted by a display panel according to a first embodiment of the present disclosure. FIG. 11 is a contour map for each color emitted by a display panel according to a second embodiment of the present disclosure. FIG. 12 is a contour map for each color emitted by a display panel according to a third embodiment of the present disclosure.

The examples of FIGS. 10 to 12 are contour maps for respective colors emitted by display panels according to first to third embodiments of the present disclosure. The display panels according to the first to third embodiments have the structure of the display panel described with reference to the examples of FIGS. 1 to 3 but differ from one another with regard to the thickness of the second electrode (cathode). As shown in FIG. 2, the first light-emitting layer B-EML may have an emission peak at a wavelength not less than 450 nm and not more than 470 nm, and the second light-emitting layer R-EML may have an emission peak at a wavelength not less than 600 nm and not more than 619 nm. The emission peak of the first light-emitting layer may be shifted to a longer wavelength, and the emission peak of the second light-emitting layer may be shifted to a shorter wavelength, so that the difference in the emission peak between the first and second light-emitting layers may be not less than 136 nm and less than 160 nm.

As can be seen from FIGS. 10 to 12, when the thickness of the second electrode is gradually increased, the blue, green, and red emission regions may be narrowed, and the emission peaks may be also narrowed. For example, as can be seen from FIGS. 10 to 12, when blue or green light is emitted, the driving voltage required for blue or green light emission may be lower than the driving voltage required for red light emission. Therefore, no emission of light of other colors may be observed.

As described above, in the display panel and the display device of the present disclosure, the area where the PL spectrum of each light-emitting layer overlaps outcoupling of the other colors may be reduced by adjusting the emission peak wavelength of the dopant in the light-emitting layer in the white organic light-emitting stack and increasing the thickness of the second electrode. Therefore, light leakage may be reduced or prevented.

FIGS. 9 and 10 show that the overlap between blue outcoupling and the red PL spectrum during red light emission may be reduced even when the thickness of the second electrode is 20 nm. FIGS. 11 and 12 show that the thickness of the second electrode is increased to 30 nm and 40 nm to narrow both red and blue light emission regions and to narrow the peak wavelength region, so that interference of emission of blue light during emission of red light may be reduced or prevented.

As the thickness of the second electrode increases, the effect of reducing or preventing light emission of other colors may also be improved, and the color gamut may be increased. However, in the display panel and the display device of the present disclosure, the thickness of the second electrode may be set to 50 nm or less to reduce or prevent light emission efficiency from decreasing to a certain level.

Table 3 below shows the PL peak value of the red dopant having the effect of reducing or preventing emission of other colors. These values were measured while the PL peak value of the blue dopant was sequentially changed from 445 nm to 466 nm when the thickness of the second electrode was not less than 20 nm and not more than 35 nm.

TABLE 3

| PL peak of blue dopant [nm] | Possible PL peak of red dopant [nm] |
|---|---|
| 445 | None |
| 446 | 612~614 |
| 447 | 612~614 |
| 448 | 612~617 |
| 449 | 612~617 |
| 450 | 612~617 |
| 451 | 612~617 |
| 452 | 612~617 |
| 453 | 612~620 |
| 454 | 612~620 |
| 455 | 612~620 |
| 456 | 612~617 |
| 457 | 612~617 |
| 458 | 612~617 |
| 459 | 614-617 |
| 460 | 614-617 |
| 461 | 614-615 |
| 462 | 614-615 |
| 463 | 614-615 |
| 464 | 614-615 |
| 465 | None |

With reference to Table 3, when the second electrode (cathode) had a thickness not less than 20 nm and not more than 35 nm, when the first light-emitting layer had an emission peak at a wavelength of not less than 446 nm and not more than 464 nm, and when the second light-emitting layer had an emission peak at a wavelength of not less than 612 nm and not more than 620 nm, the display panel may function without a color filter because the first to third light-emitting layers have a narrow full width at half maximum and strong cavity characteristics and may emit light without interference of other colors. Here, the difference in the emission peak between the first light-emitting layer and the second light-emitting layer may be from 148 nm to 174 nm.

Table 4 below shows the PL peak value of the red dopant having the effect of reducing or preventing emission of other colors, measured while the PL peak value of the blue dopant was sequentially changed from 451 nm to 468 nm when the thickness of the second electrode was more than 35 nm and not more than 50 nm.

TABLE 4

| PL peak of blue dopant [nm] | Possible PL peak of red dopant [nm] |
|---|---|
| 451 | None |
| 452 | 609~614 |
| 453 | 606~618 |
| 454 | 606~623 |
| 455 | 606~623 |
| 456 | 602~623 |
| 457 | 602~623 |
| 458 | 602~623 |
| 459 | 602~623 |
| 460 | 602~623 |
| 461 | 602~617 |
| 462 | 602~618 |
| 463 | 602~618 |
| 464 | 602~618 |
| 465 | 606-616 |
| 466 | 606-616 |
| 467 | 606-616 |
| 468 | None |

With reference to Table 4, when the second electrode (cathode) had a thickness more than 35 nm and not more than 50 nm, when the first light-emitting layer had an emission peak at a wavelength of not less than 452 nm and not more than 467 nm, and when the second light-emitting layer had an emission peak at a wavelength of not less than 602 nm or not more than 623 nm, the first to third light-emitting layers had a narrow full width at half maximum and strong cavity characteristics, and might emit light without interference of other colors. Thus, the display panel can function without a color filter. Here, when the difference in the emission peak between the first light-emitting layer and the second light-emitting layer was 135 nm to 171 nm, it may be effective in reducing or preventing interference caused by emission of light of other colors in the display panel. Comparing Table 3 with Table 4, it can be seen that, when the transmittance of the second electrode increased, the strong cavity effect improved, and thus the effect may be obtained in a wider range of PL peak wavelengths.

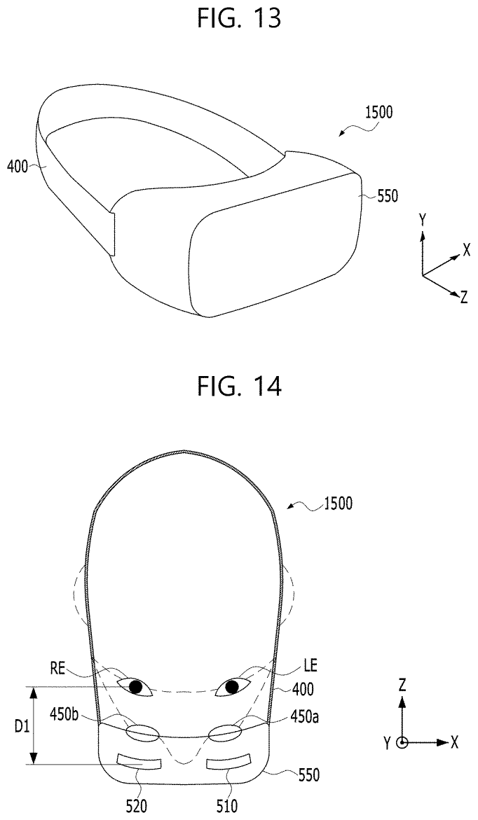

Hereinafter, examples of application of the display panel of the present disclosure to various types of wearable display devices will be described. FIG. 13 is a perspective view of a display device according to a first aspect of the present disclosure. FIG. 14 is a top view of FIG. 13.

As shown in FIGS. 13 and 14, the display device 1500 according to the first aspect of the present disclosure may be provided in the form of a band configured to view virtual reality. The display device 1500 may include on the inner surface thereof an accommodation structure 550 configured to accommodate a first display panel 510 and a second display panel 520 in regions corresponding to the viewer's eyes LE and RE, respectively, and first and second lens units 450a and 450b, configured to converge images on the viewer's eyes, between the second display panel 520 and the first display panel 510 and the viewer's eyes LE and RE.

In this case, the display device 1500 may move together with the viewer's head. Thus, the vertical distance between the first and second display panels 510 and 520 and the viewer's eyes LE and RE may be constant regardless of movement of the viewer.

Accordingly, the viewpoint may be fixed when the left eye LE looks at the first display panel 510 and the right eye RE looks at the second display panel 520. Thus, the left and right eyes may see images emitted from the first and second display panels 510 and 520 without any deviation of the viewing angle.

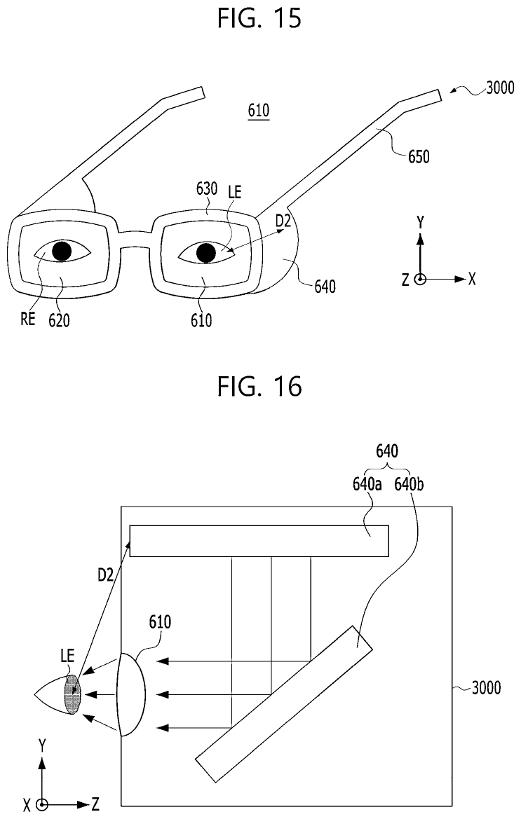

FIG. 15 is a perspective view illustrating a display device according to a second aspect of the present disclosure. FIG. 16 is a diagram illustrating the relationship between the display device of FIG. 15 and a viewer's eye.

As shown in FIGS. 15 and 16, the display device according to the second aspect of the present disclosure may have, for example, a form applicable to augmented reality. The display device may include transparent lens units 610 and 620 at the front side thereof facing both eyes LE and RE to be in the form of eyeglasses configured to visually recognize the external environment. However, embodiments of the present disclosure are not limited thereto, and the transparent lens units 610 and 620 may also be provided at the front side facing the two eyes in the form of a helmet or a band to visually recognize the external environment and view augmented reality.

In addition, a head-mounted display device 3000 according to a second aspect of the present disclosure may include a transparent lens unit, including separated first and second transparent lenses 610 and 620 at the front side thereof facing both eyes LE and RE, and an accommodation structure 650 configured to surround the first and second transparent lenses 610 and 620 in the form of a frame 630 and to enable the head-mounted display device 3000 to be hung on both ears of the viewer on both sides of the viewer's eyes (LE, RE). In addition, the accommodation structure 650 may include, on both sides of the eyes LE and RE of a viewer, an image transfer unit 640, including a display panel 640a spaced apart from each eye by a constant oblique distance D2, and a mirror reflector 640b, which may transfer an image displayed from the display panel 640a to the transparent lens units 610 and 620.

The display panel and the display device using the same according to various embodiments of the present disclosure may have the following effects. The display panel and the display device using the same according to various embodiments of the present disclosure enable light emission in a strong cavity mode for the color of emitted light in each subpixel in the display panel close to the viewer's eyes and thus exhibit EL characteristics in a narrow wavelength width. As a result, even if the subpixels emit light through a common white organic stack, the color filter may be omitted for each subpixel by varying the optical distance. Accordingly, it may be possible to improve the pure color efficiency as well as color gamut. In addition, there may be an additional advantage of simplifying the structure of the display panel.

In addition, the red PL (photoluminescence) peak is shifted to a short wavelength and the blue PL is shifted to a long wavelength by changing the material of the light-emitting layer provided in the white organic stack. Thus, the area where the blue outcoupling region overlaps the red PL peak spectrum may be reduced, and light leakage at a blue wavelength may be inhibited during emission of red light. Therefore, the color filter may be omitted.

The above-described features, structures, and effects of the present disclosure are included in at least one example embodiment of the present disclosure, but are not limited to only one example embodiment. Furthermore, the features, structures, and effects described in at least one example embodiment of the present disclosure may be implemented through combination with or modification of other embodiments by those skilled in the art. Therefore, content associated with the combination and modification should be construed as being within the scope of the present disclosure.

It will be apparent to those skilled in the art that various substitutions, modifications, and variations are possible within the scope of the present disclosure without departing from the spirit and scope of the disclosure. Therefore, it is intended that embodiments of the present disclosure cover the various substitutions, modifications, and variations of this disclosure, provided they come within the scope of the appended claims and their equivalents.

What is claimed is:

1. A display panel comprising:
a substrate having first to third subpixels each including a reflective electrode;
a first electrode vertically spaced apart from a lower surface of the reflective electrode by a gradually increasing distance;
a white organic stack on the first electrode;
a second electrode on the white organic stack, the second electrode having reflectivity and transmittance, and a thickness of from 20 nm to 50 nm;
a capping layer on the second electrode; and
a transparent protective layer on the capping layer.

2. The display panel according to claim 1, wherein the white organic stack comprises:
a first stack comprising
a first light-emitting layer to emit light of a blue wavelength,
a first common layer under the first light-emitting layer,
a second common layer on the first light-emitting layer, and
a charge generation layer contacting the second common layer; and
a second stack on the charge generation layer, the second stack comprising:
a second light-emitting layer to emit light of a red wavelength,
a third light-emitting layer to emit light of a green wavelength, the second light-emitting layer and third light-emitting layer being in contact with each other;
a third common layer under the second light-emitting layer; and
a fourth common layer on the third light-emitting layer.

3. The display panel according to claim 2, wherein the panel is configured to emit light such that:
light emitted from the first light-emitting layer at the first subpixel is emitted in a single strong cavity mode through the second electrode,
light emitted from the third light-emitting layer at the second subpixel is emitted in a single strong cavity mode through the second electrode, and
light emitted from the second light-emitting layer at the third subpixel is emitted in a single strong cavity mode through the second electrode.

4. The display panel according to claim 2, wherein a difference in wavelengths of emission peaks of the first light-emitting layer and the second light-emitting layer is from 135 nm to 174 nm.

5. The display panel according to claim 2, wherein
the second electrode has a thickness not less than 20 nm and not more than 35 nm,
the first light-emitting layer has an emission peak at a wavelength not less than 446 nm and not more than 464 nm, and
the second light-emitting layer has an emission peak at a wavelength not less than 612 nm and not more than 620 nm.

6. The display panel according to claim 2, wherein
the second electrode has a thickness more than 35 nm and not more than 50 nm,
the first light-emitting layer has an emission peak at a wavelength not less than 452 nm and not more than 467 nm, and
the second light-emitting layer has an emission peak at a wavelength not less than 602 nm and not more than 623 nm.

7. The display panel according to claim 2, wherein
the first light-emitting layer has an emission peak at a wavelength not less than 450 nm and not more than 470 nm, and
the second light-emitting layer has an emission peak at a wavelength not less than 600 nm and not more than 619 nm.

8. The display panel according to claim 2, wherein, at the third subpixel, a full width at half maximum of light emitted to the second light-emitting layer through the second electrode is not less than 10 nm and not more than 24 nm.

9. The display panel according to claim 1, wherein the first electrode comprises a transparent oxide containing at least one of indium, zinc, and tin, and
the second electrode comprises at least one of magnesium, a magnesium alloy, silver, and a silver alloy.

10. The display panel according to claim 1, wherein
the reflective electrode at the first subpixel and the first electrode are in contact with each other, and
the display panel further comprises a transparent inorganic layer between the first electrode and the reflective electrode at the second subpixel and the third subpixel.

11. The display panel according to claim 1, wherein the transparent protective layer comprises an encapsulation layer.

12. The display panel according to claim 1, wherein there is no member limiting a color of emitted light on the transparent protective layer.

13. The display panel according to claim 1, further comprising:
a thin-film transistor at each of the first to third subpixels connected to the first electrode.

14. The display panel according to claim 1, wherein the substrate comprises any one of a transparent glass substrate, a transparent plastic substrate, and a silicon substrate.

15. A display device comprising:
a display panel comprising:
a substrate having first to third subpixels each including a reflective electrode;
a first electrode vertically spaced apart from a lower surface of the reflective electrode by a gradually increasing distance;
a white organic stack on the first electrode;
a second electrode on the white organic stack, the second electrode having reflectivity and transmittance, and a thickness of 20 nm to 50 nm;
a capping layer on the second electrode; and
a transparent protective layer on the capping layer;
an accommodation structure to accommodate the display panel; and
an air gap between the accommodation structure and the transparent protective layer.

16. The display device according to claim 15, wherein the second electrode has a thickness of from 20 nm to 50 nm.

17. The display device according to claim 15, wherein the white organic stack comprises:
a first stack comprising
a first light-emitting layer to emit light of a blue wavelength,
a first common layer under the first light-emitting layer,
a second common layer on the first light-emitting layer, and
a charge generation layer contacting the second common layer; and
a second stack on the charge generation layer, the second stack comprising:
a second light-emitting layer to emit light of a red wavelength,
a third light-emitting layer to emit light of a green wavelength, the second light-emitting layer and third light-emitting layer contacting each other;
a third common layer under the second light-emitting layer; and
a fourth common layer on the third light-emitting layer.

18. The display device according to claim 17, wherein the first light-emitting layer has an emission peak at a wavelength not less than 450 nm and not more than 470 nm, and
the second light-emitting layer has an emission peak at a wavelength not less than 600 nm and not more than 619 nm.

19. The display device according to claim 16, wherein the display device is configured such that light passing through the second electrode of the display panel is emitted through the air gap.

20. The display device according to claim 17, wherein the display device is configured such that:
light emitted from the first light-emitting layer at the first subpixel is emitted in a single strong cavity mode through the second electrode,
light emitted from the third light-emitting layer at the second subpixel is emitted in a single strong cavity mode through the second electrode, and
light emitted from the second light-emitting layer at the third subpixel is emitted in a single strong cavity mode through the second electrode.

21. The display device according to claim 15, wherein the substrate is configured to be fixed at a predetermined distance from eyes of a viewer.

22. The display device according to claim 17, wherein the display device is configured such that light passing through the second electrode passes through the capping layer, the transparent protective layer, and the air gap, and has an identical light intensity ratio between red, green, and blue lights.

23. The display device according to claim 15, comprising a first display panel and a second display panel separately disposed at regions in the accommodation structure, the regions correspond to both eyes of a viewer.

24. The display device according to claim 23, further comprising first and second lens units configured to converge an image to each eye of the viewer and be located between each of the first and second display panels and each eye of the viewer.

25. The display device according to claim 24, wherein the accommodation structure is configured such that the first and second display panels are each provided at sides of both eyes of the viewer, and
the display device further comprises first and second mirror reflective electrodes to reflect and transmit images emitted from the first and second display panels to the first and second lens units, respectively.
